(19) United States
(12) Patent Application Publication
(10) Pub. No.: US 2026/0123431 A1
(43) Pub. Date: Apr. 30, 2026

(54) CERAMIC SUBSTRATE UNIT AND MANUFACTURING METHOD THEREFOR

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/836,415

(22) PCT Filed: Feb. 7, 2023
(86) PCT No.: PCT/KR2023/001680

§ 371 Date: Aug. 7, 2024

(30) Foreign Application Priority Data
Feb. 7, 2022 (KR) 10-2022-0015336
Feb. 14, 2022 (KR) 10-2022-0018767

(51) Int. Cl. H01L 23/00; H01L 21/48; H01L 23/15; H01L 23/373; H01L 23/473; H01L 23/498; H01L 23/538; H01L 25/065

(52) U.S. Cl. CPC H10W 42/121; H10W 40/258; H10W 40/47; H10W 70/023; H10W 70/611; H10W 70/66; H10W 70/685; H10W 70/692; H10W 90/00; H10W 90/794

(57) ABSTRACT

The present disclosure relates to a ceramic substrate unit and a manufacturing method therefor, in which the volume of an upper electrode bonded to an upper metal layer of a ceramic substrate is calculated, and multiple separated heat sinks are formed so as to have a predetermined volume corresponding to the volume of the upper electrode, and thus warpage occurring at a high temperature may be suppressed.

### TECHNICAL FIELD

The present disclosure relates to a ceramic substrate unit and a manufacturing method therefor, and more specifically, to a ceramic substrate unit formed so that an upper electrode and a heat sink may be applied to a high-output power module, and a manufacturing method therefor.

### BACKGROUND ART

In general, electric vehicles require an inverter for converting a direct current voltage provided from a high-voltage battery into an alternating current three-phase voltage to drive a motor.

This inverter is assembled with a power module for adjusting a high voltage of a driving battery to a state suitable for the motor and supplying the adjusted voltage. The power module includes a semiconductor chip for converting power, and the semiconductor chip generates high temperature heat due to a high-voltage and high-current operation. When this heat continues, there is a problem in that the semiconductor chip deteriorates, and the performance of the power module deteriorates.

In order to solve this, a heat sink is provided on at least one surface of a ceramic or metal substrate to prevent a deterioration phenomenon of the semiconductor chip due to heat through a heat dissipation function of the heat sink. The heat sink is made of a metal material for heat dissipation, and since the metallic heat sink also has a limitation in heat dissipation, when heat exceeding the limitation is generated, cooling efficiency is degraded rapidly, causing a failure. In addition, there is a problem that the characteristics of the substrate on which semiconductor chips are mounted are degraded due to the occurrence of warpage, etc. caused by heat.

Matters described above in the background art are intended to help understanding of the background of the disclosure and may include matters not related to the known related art.

### SUMMARY OF INVENTION

### Technical Problem

The present disclosure has been made in efforts to solve the problems and is directed to providing a ceramic substrate unit and a manufacturing method therefor, in which an upper electrode and a heat sink may be respectively bonded to upper and lower metal layers of a ceramic substrate, thereby having excellent electrical conductivity and thermal conductivity and effectively dissipating heat generated from a semiconductor chip.

### Solution to Problem

A ceramic substrate unit according to an embodiment of the present disclosure for achieving the object may include a ceramic substrate having a metal layer provided on upper and lower surfaces of a ceramic base, and an upper electrode bonded to an upper metal layer of the ceramic substrate and formed so that a semiconductor chip is mounted thereon, and a heat sink bonded to a lower metal layer of the ceramic substrate, wherein the heat sink is partitioned into a plurality of heat sinks.

The upper electrode and the heat sink may each be formed in a thickness of 0.6 mm or more to 9.0 mm or less.

The heat sink may be partitioned into a plurality of heat sinks by a space formed by etching a portion of the heat sink in a thickness direction. A bottom surface of the lower metal layer may be exposed through the space.

In addition, the heat sink may be partitioned into a plurality of heat sinks to have a predetermined volume corresponding to a volume of the upper electrode. Here, a volume ratio obtained by dividing a total volume of the upper electrode by a total volume of the heat sink may range from 0.9 to 1.1.

The plurality of heat sinks may each include a flat portion having an upper surface bonded to the lower metal layer, and a plurality of protrusions disposed on a lower surface of the flat portion and forming a passage through which refrigerant flows, and the flat portions may be disposed to be spaced apart from each other with the space interposed therebetween. Here, a thickness of the flat portion may be larger than a thickness of the protrusion.

The plurality of heat sinks may each have the same area of the flat portion. In addition, the plurality of heat sinks may each have the same number of protrusions.

Two heat sinks whose end portions face among the plurality of heat sinks may each have the protrusion located on the same virtual line when the virtual line is drawn in a direction in which the end portions face.

The plurality of protrusions may be provided in a bar shape and disposed horizontally at an interval.

The ceramic substrate unit may further include a first bonding layer disposed between the upper metal layer of the ceramic substrate and the upper electrode and bonding the ceramic substrate and the upper electrode, wherein the first bonding layer may be made of a material including at least one of Ag, Cu, AgCu, and AgCuTi or a material including an Ag sintered body.

The ceramic substrate unit may further include a second bonding layer disposed between the lower metal layer of the ceramic substrate and the heat sink and bonding the ceramic substrate and the heat sink, wherein the second bonding layer may be made of a material including at least one of Ag, Cu, AgCu, and AgCuTi or a material including an Ag sintered body. In addition, the upper electrode and the heat sink may be made of any one of Cu, Al, and a Cu alloy.

A method manufacturing a ceramic substrate unit according to an embodiment of the present disclosure may include preparing a ceramic substrate including a metal layer provided on upper and lower surfaces of a ceramic base, bonding an upper electrode formed so that a semiconductor chip is mounted thereon to an upper metal layer of the ceramic substrate, preparing heat sinks partitioned into a plurality of heat sinks, and bonding the heat sink to a lower metal layer of the ceramic substrate.

The preparing of the heat sink may include forming heat sinks partitioned into the plurality of heat sinks by a space formed by etching a portion of the heat sink in a thickness direction.

The preparing of the heat sink may include forming the space so that a volume ratio obtained by dividing a total volume of the upper electrode by a total volume of the heat sink ranges from 0.9 to 1.1.

The bonding of the upper electrode to the upper metal layer of the ceramic substrate may include bonding the upper electrode to the upper metal layer via a first bonding layer disposed between the upper metal layer and the upper electrode, and the first bonding layer may be made of a material including at least one of Ag, Cu, AgCu, and AgCuTi or a material including an Ag sintered body.

The bonding of the heat sink may include bonding the heat sink to the lower metal layer via a second bonding layer disposed between the lower metal layer and the heat sink, and the second bonding layer may be made of a material including at least one of Ag, Cu, AgCu, and AgCuTi or a material including an Ag sintered body.

### Advantageous Effects of Invention

According to the present disclosure, since the heat sink is partitioned into the plurality of heat sinks by the space formed by etching the portion of the heat sink in the thickness direction, the volume ratio of the upper electrode/heat sink may be controlled to be within the range of 0.9 to 1.1 without changing the thickness of the heat sink, thereby suppressing the warpage caused by the difference in volumes of the upper electrode and the heat sink.

In addition, according to the present disclosure, it is possible to suppress the warpage phenomenon caused by the difference in volumes of the upper electrode and the heat sink, thereby enhancing bonding reliability, maximizing the heat dissipation effect, and reducing the defect rate to increase productivity.

In addition, according to the present disclosure, since the upper electrode is made of any one of Cu, Al, a CuMo alloy, and a CuW alloy and formed in a thickness of 0.6 mm or more to 9.0 mm or less, the high voltage and high current can be electrically conducted, and the upper electrode can be applied to the high-output power conversion power module by having excellent thermal conductivity.

In addition, according to the present disclosure, since the heat sink is made of any one of Cu, Al, a CuMo alloy, and a CuW alloy and formed in a thickness of 0.6 mm or more to 9.0 mm or less, the high heat dissipation conditions required for the power module can be satisfied, and warpage can be suppressed.

In addition, according to the present disclosure, even when high-temperature heat is generated from the semiconductor chip, the heat can be quickly cooled by the heat sink on which the passage through which refrigerant flows is formed, and thus the semiconductor chip can be maintained at the constant temperature without deterioration.

### BRIEF DESCRIPTION OF DRAWINGS

FIG. 1 is a perspective view showing a ceramic substrate unit according to one embodiment of the present disclosure.

FIG. 2 is a side view showing the ceramic substrate unit according to one embodiment of the present disclosure.

FIG. 3 is a bottom view showing the ceramic substrate unit according to one embodiment of the present disclosure.

FIG. 4 is a bottom view showing a ceramic substrate unit according to another embodiment of the present disclosure.

FIG. 5 is a bottom view showing a comparative example in which a heat sink is not partitioned in the ceramic substrate unit.

FIG. 6 is a flowchart showing a method of manufacturing the ceramic substrate unit according to one embodiment of the present disclosure.

### DESCRIPTION OF EMBODIMENTS

Hereinafter, exemplary embodiments according to the present disclosure will be described in detail with reference to the accompanying drawings.

The embodiments are provided to more completely describe the present disclosure to those skilled in the art, and the following embodiments may be modified in various different forms, and the scope of the present disclosure is limited to the following embodiments. Rather, the embodiments are provided to make the disclosure more faithful and complete and fully convey the spirit of the present disclosure.

Terms used herein are intended to describe specific embodiments and are not intended to limit the present disclosure. In addition, in the present specification, singular forms may include plural forms unless the context clearly indicates otherwise.

In the description of the embodiment, when each layer (film), area, pattern, or structure is described as being formed “on” or “under” a substrate, each layer (film), area, pad, or patterns, “on” and “under” include both cases of being formed “directly” or “indirectly with other elements interposed therebetween.” In addition, in principle, the reference for “above” or “under” each layer are based on the drawing.

The drawings are only intended to help understanding of the spirit of the present disclosure and should not be construed as limiting the scope of the present disclosure by the drawings. In addition, in the drawings, a relative thickness and length, or a relative size may be exaggerated for convenience and clarity of description.

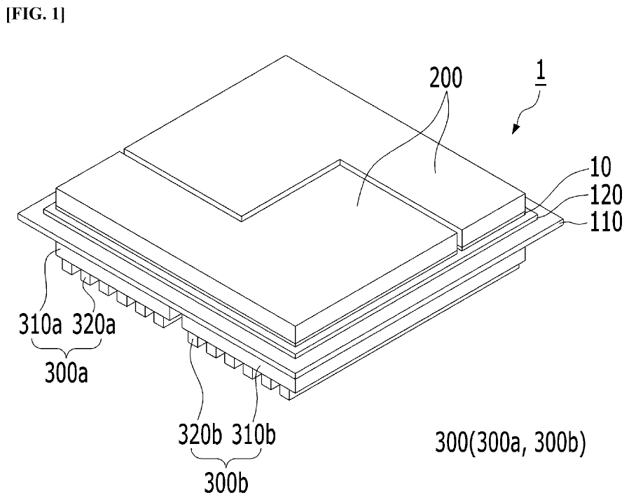

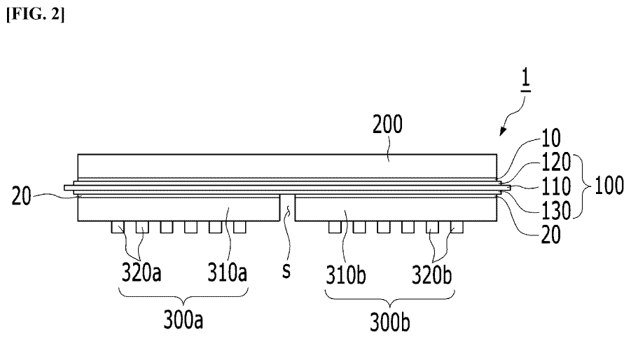

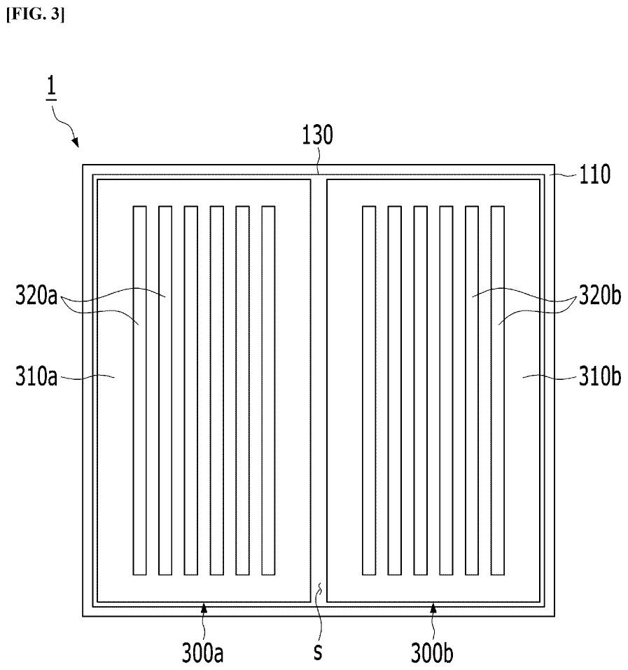

FIG. 1 is a perspective view showing a ceramic substrate unit according to one embodiment of the present disclosure, FIG. 2 is a side view showing the ceramic substrate unit according to one embodiment of the present disclosure, and FIG. 3 is a bottom view showing the ceramic substrate unit according to one embodiment of the present disclosure.

As shown in FIGS. 1 to 3, a ceramic substrate unit 1 according to an embodiment of the present disclosure may include a ceramic substrate 100, an upper electrode 200, and a heat sink 300.

The ceramic substrate 100 may be any one of an active metal brazing (AMB) substrate, a direct bonded copper (DBC) substrate, and a thick printing copper (TPC) substrate. These ceramic substrates are substrates in which a metal is directly bonded to a ceramic base. In the embodiment of the present disclosure, the ceramic substrate 100 may include a ceramic base 110, and an upper metal layer 120 and a lower metal layer 130 that are formed on upper and lower surfaces of the ceramic base 110 to increase the heat dissipation efficiency of heat generated from a semiconductor chip. Here, a thickness of the ceramic base 110 may be 0.32 t, and a thickness of each of the upper and lower metal layers 120 and 130 may be 0.3 t.

The ceramic base 110 may be made of an oxide-based or nitride-based ceramic material. For example, the ceramic base 110 may be any one of alumina (Al₂O₃), AlN, SiN, Si₃N₄, and zirconia toughened alumina (ZTA), but is not limited thereto.

The upper metal layer 120 may be formed on the upper surface of the ceramic base and provided in a shape of a circuit pattern. For example, the upper metal layer 120 may be provided in the form of a metal foil and brazing-bonded to the upper surface of the ceramic base 110 and then formed of an electrode pattern for mounting a semiconductor chip and an electrode pattern for mounting a driving element by etching. For example, the upper metal layer 120 may be made of one of Cu, a Cu alloy (CuMo, etc.), OFC, EPT Cu, and Al. OFC is anoxic copper.

The lower metal layer 130 may be formed on the lower surface of the ceramic base 110 and formed of a flat plate to facilitate heat transfer. The lower metal layer 130 may be provided in the form of a metal foil made of one of Cu, a Cu alloy (CuMo, etc.), OFC, EPT Cu, and Al and brazing-bonded to the lower surface of the ceramic base 110.

The upper electrode 200 may be bonded to the upper metal layer 120 of the ceramic substrate 100 and formed so that the semiconductor chip (not shown) is mounted thereon. The upper electrode 200 may be formed in a shape corresponding to the upper metal layer 120 of the ceramic substrate 100 to have a lower surface bonded to the upper metal layer 120 and formed to have a predetermined thickness.

Specifically, the upper electrode 200 may be formed to have a thickness of 0.6 mm or more to 9.0 mm or less. As described above, when the upper electrode 200 is formed thick, a high voltage and high current may be electrically conducted. Since railway vehicles perform high-output power conversion compared to general vehicles, the upper electrode 200 should have high electrical conductivity and high thermal conductivity for heat dissipation. In the ceramic substrate unit 1 according to the embodiment of the present disclosure, since the upper electrode 200 is made of any one of Cu, Al, a CuMo alloy, and a CuW alloy and formed in a relatively large thickness of 0.6 mm or more to 9.0 mm or less, there is an advantage of being applicable to high-output power conversion power modules by having excellent electrical and thermal conductivity.

The semiconductor chip mounted on the upper electrode 200 may be a semiconductor chip such as SiC, GaN, Si, an LED, or a VCSEL. The semiconductor chip may be bonded to an upper surface of the upper electrode 200 by a bonding layer (not shown) containing solder or Ag paste. In this case, at least two semiconductor chips may be bonded to the upper electrode 200, and the semiconductor chips may be electrically connected by wire bonding, flip-chip bonding, etc.

The upper electrode 200 may be bonded to the upper metal layer 120 of the ceramic substrate 100 via a first bonding layer 10. In this case, the first bonding layer 10 may be a brazing bonding layer or an Ag sintering bonding layer made of a material including at least one of Ag, Cu, AgCu, and AgCuTi. When the first bonding layer 10 is a brazing bonding layer, the brazing bonding layer may be disposed between the upper metal layer 120 of the ceramic substrate 100 and the upper electrode 200 and may integrally bond the ceramic substrate 100 and the upper electrode 200 at a brazing temperature. The brazing temperature may be 450° C. or higher. Ag, AgCu, and AgCuTi may serve to increase bonding strength due to high thermal conductivity and at the same time, facilitate heat transfer between the ceramic substrate 100 and the upper electrode 200, thereby increasing heat dissipation efficiency.

When the first bonding layer 10 is an Ag sintered bonding layer, the first bonding layer 10 may be made of a material including an Ag sintered body. For example, when the first bonding layer 10 is an Ag sintered body film, the Ag sintered body film may be disposed between the upper metal layer 120 of the ceramic substrate 100 and the upper electrode 200, and in this state, by applying a pressure to the above assembly and hardening the same, the ceramic substrate 100 and the upper electrode 200 may be integrally bonded. As described above, a method of hardening the Ag sintered body film enables bonding at a relatively low pressure and low temperature, has high high-temperature stability, and has excellent bonding strength of about 80 MPa. As described above, the ceramic substrate 100 and the upper electrode 200 are airtightly bonded by a bonding method such as brazing bonding or Ag sintering bonding, thereby having high bonding strength and excellent high-temperature reliability. The ceramic substrate 100 and the upper electrode 200 may be temporarily bonded by thermochemical bonding and then brazing-bonded or Ag sintering-bonded. In this case, the thermochemical bonding may be bonding using heat fusion, an adhesive, a gluing agent, etc.

Meanwhile, since the ceramic substrate 100 has a large volume difference when comparing a total volume of the lower metal layer 130 in the form of a flat plate with a total volume of the upper metal layer 120 formed of a circuit pattern, a warpage phenomenon occurs at a high temperature.

In addition, the heat sink 300 bonded to the lower metal layer 130 of the ceramic substrate 100 via the second bonding layer 20 is made of Cu, Al, etc. with excellent thermal conductivity for cooling, and since the material has a thermal expansion coefficient of 17.8 ppm/m·K or more, there is a problem that warpage greatly occurs at a high temperature of 200° C. or higher. As described above, warpage occurs in the bonding structure of the ceramic substrate 100 and the heat sink 300 depending on the size and shape of each bonding material, a thermal expansion coefficient, etc.

Since the upper metal layer 120 of the ceramic substrate 100 is formed of a circuit pattern, the upper metal layer 120 is designed to have a fixed shape, thickness, length, etc. in many cases. In addition, since the upper electrode 200 is formed in a shape corresponding to the upper metal layer 120, bonded to the upper metal layer 120, and formed so that the semiconductor chips are mounted thereon, the upper electrode 200 is designed to have a fixed shape, thickness, length, etc. in many cases.

Therefore, the ceramic substrate unit 1 according to the embodiment of the present disclosure may calculate a volume of the upper electrode 200 bonded to the upper metal layer 120 of the ceramic substrate 100 and form the heat sink 300 partitioned into a plurality of heat sinks to have a predetermined volume corresponding to the volume of the upper electrode 200, thereby suppressing warpage occurring at a high temperature.

Specifically, it is preferable that a volume ratio obtained by dividing a total volume of the upper electrode 200 by a total volume of the heat sink 300 is designed to be within a range of 0.9 to 1.1, and to minimize warpage, it is more preferable that the volume ratio is designed to be close to 1.0. Here, the total volume may be calculated by multiplying a total area by a thickness.

Since the ceramic substrate unit 1 according to the present disclosure may be applied to a power module, thicknesses of the upper electrode 200 and the heat sink 300 may be designed in consideration of a thickness of the power module. Since the power module is provided with a semiconductor chip, the power module is sealed with an epoxy-based molding resin to protect the semiconductor chip from an external environment, and in this case, since a molding mold is used, the thicknesses of the upper electrode 200 and the heat sink 300 may be designed in consideration of a height of the molding mold. In addition, the heat sink 300 may be designed to a thickness optimized for heat dissipation. As described above, the thicknesses of the upper electrode 200 and the heat sink 300 are designed in consideration of a product, process conditions, heat dissipation, etc., and thus it is difficult to change the same later.

The ceramic substrate unit 1 according to the present disclosure can solve a problem that it is difficult to suppress warpage due to the limitation in changing the thicknesses of the upper electrode 200 and the heat sink 300. That is, since the ceramic substrate unit 1 according to the present disclosure has the heat sink 300 that is partitioned into the plurality of heat sinks by a space s formed by etching a portion of the heat sink 300 in the thickness direction, the volume ratio of the upper electrode 200 and the heat sink 300 may be adjusted to be within the range of 0.9 to 1.1 without changing the thickness of the heat sink 300. As described above, according to the present disclosure, it is possible to suppress the warpage phenomenon caused by the volume difference between the upper electrode 200 and the heat sink 300.

The heat sink 300 may be partitioned in various forms by the space s. For example, as shown in FIG. 3, the heat sink 300 may be partitioned into a plurality of heat sinks 300a and 300b having a quadrangular cross section and the same area by the space s etched in a straight line shape.

Referring to FIGS. 2 and 3, a bottom surface of the lower metal layer 130 may be exposed through the space s formed by etching a portion of the heat sink 300 in the thickness direction. Although not shown, a bottom surface of the second bonding layer 20 to be described below may be exposed through the space s. That is, when the portion of the heat sink 300 is etched in the thickness direction and the second bonding layer 20 is etched together, the bottom surface of the lower metal layer 130 may be exposed through the space s, and when the second bonding layer 20 is not etched, the bottom surface of the second bonding layer 20 may be exposed through the space s.

The heat sink 300 may be operated by any one of an air-cooled method or a water-cooled method. Here, for the air-cooled method, air may be supplied as refrigerant, and for the water-cooled method, cooling water, liquid nitrogen, alcohol, or other solvents may be supplied by being circulated as refrigerant by a pumping force. For example, when the heat sink 300 is operated by the water-cooled method, heat may be quickly absorbed and discharged as a flow rate of the refrigerant is adjusted and forcibly cooled by the continuously circulating refrigerant, thereby preventing overheating of the semiconductor chip.

The heat sink 300 may be any one of micro channel, pin fin, micro jet, and slit types, and in the present embodiment, a slit type heat sink 300 in which a plurality of bar-shaped protrusions 320 are horizontally disposed at intervals will be described.

The first and second heat sinks 300a and 300b may include flat portions 310a and 310b whose upper surfaces are bonded to the lower metal layer 130 of the ceramic substrate 100, and a plurality of protrusions 320a and 320b disposed on lower surfaces of the flat portions 310a and 310b, respectively.

The flat portions 310a and 310b may be provided in the form of a flat plate so that the upper surfaces may be in direct contact with the lower metal layer 130 and bonding strength can be increased by maximizing bonding areas with the lower metal layer 130. The plurality of protrusions 320a and 320b may be disposed on the lower surfaces of the flat portions 310a and 310b at intervals and may form passages through which the refrigerant flows. Here, the flat portions 310a and 310b may be disposed to be spaced apart from each other with the space s interposed therebetween. In addition, although not shown, the plurality of protrusions 320a and 320b may be provided in various pin shapes such as a cylinder, a polygonal cylinder, a teardrop shape, and a diamond shape. The shapes of the protrusions 320a and 320b may be implemented by mold processing, etching processing, milling processing, and other processing.

The first and second heat sinks 300a and 300b may each be provided so that areas of the flat portions 310a and 310b are the same and provided so that the numbers of plurality of protrusions 320a and 320b may be the same. As an example, the number of protrusions 320a of the first heat sink 300a and the number of protrusions 320b of the second heat sink 300b may be 5, and the numbers of protrusions 320a and 320b are not limited thereto.

A thickness of the flat portion 310 may be formed to be larger than thicknesses of the plurality of protrusions 320. As an example, when the thickness of the flat portion 310 is 2.0 mm, the thickness of the protrusion 320 may be 1.0 mm. Since the flat portion 310 is a portion that is in contact with the lower metal layer 130 of the ceramic substrate 100 and directly transfers heat, when the flat portion 310 is formed to be larger than the thickness of the protrusion 320, the heat spreads widely, thereby making it easy to suppress warpage at a high temperature and improving heat dissipation performance.

In an example in which the heat sink 300 was partitioned into the first and second heat sinks 300a and 300b for warpage control as shown in FIG. 3, when the upper electrode 200 of the ceramic substrate unit 1 was made of an OFC material and had a thickness of 2.0 mm, and when the thickness of the heat sink 300 was 3.0 mm, a volume ratio obtained by dividing the total volume of the upper electrode 200 by the total volume of the heat sink 300 was found to be 0.9. In addition, an average warping value at 200° C. or higher, that is, when the volume of the heat sink 300 was larger and thus the heat sink 300 was warped convexly upward, was found to be a very small value of about 0.150 mm.

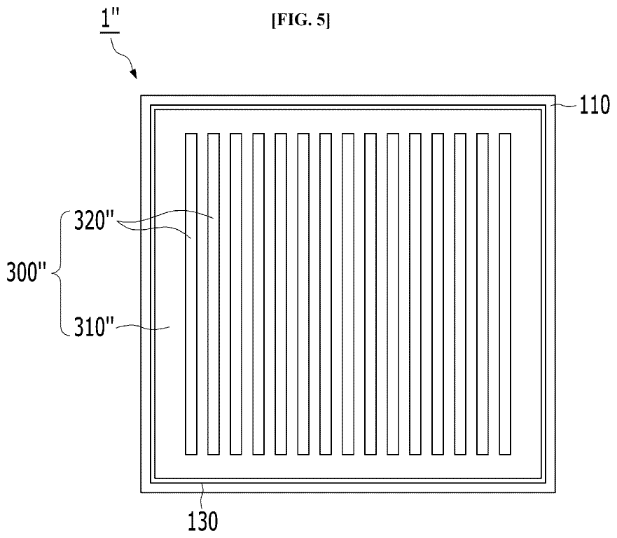

On the other hand, in a comparative example in which a heat sink 300″ was not partitioned as shown in FIG. 5, when an upper electrode 200 of a ceramic substrate unit 1″ was made of an OFC material and had a thickness of 2.0 mm and a thickness of the heat sink 300″ was 3.0 mm, a volume ratio obtained by dividing the total volume of the upper electrode 200 by the total volume of the heat sink 300″ was found to be 0.75. In addition, the average warping value in the case of negative warpage at 200° C. or higher was about 0.358 mm, indicating that a significant change occurred. As described above, when the heat sink 300″ was not partitioned and thus a volume difference between the upper electrode 200 and the heat sink 300″ was large, warping strength of the heat sink 300″ was relatively greater and the phenomenon of the heat sink 300″ warped convexly upward was found to be more severe.

As a result, the average warping value in the example in which the heat sink 300 was partitioned into the two heat sinks 300a and 300b was found to be much smaller than that in the comparative example in which the heat sink 300″ is not partitioned. This is because, as the heat sink 300 is partitioned into the first and second heat sinks 300a and 300b by the space s formed by etching the portion of the heat sink 300 in the thickness direction, the volume of the heat sink 300 is reduced in a state in which the thickness is not changed, and thus the volume ratio of the upper electrode 200 and the heat sink 300 is adjusted to be within the range of 0.9 to 1.1, thereby suppressing the warpage caused by the volume difference. As described above, according to the present disclosure, by partitioning the heat sink 300 into the plurality of heat sinks to have a predetermined volume corresponding to the volume of the upper electrode 200 designed to have the fixed shape, thickness, length, etc. and controlling the volume ratio of the upper electrode 200 and the heat sink 300 to be within a specific range, it is possible to suppress the warpage phenomenon at a high temperature.

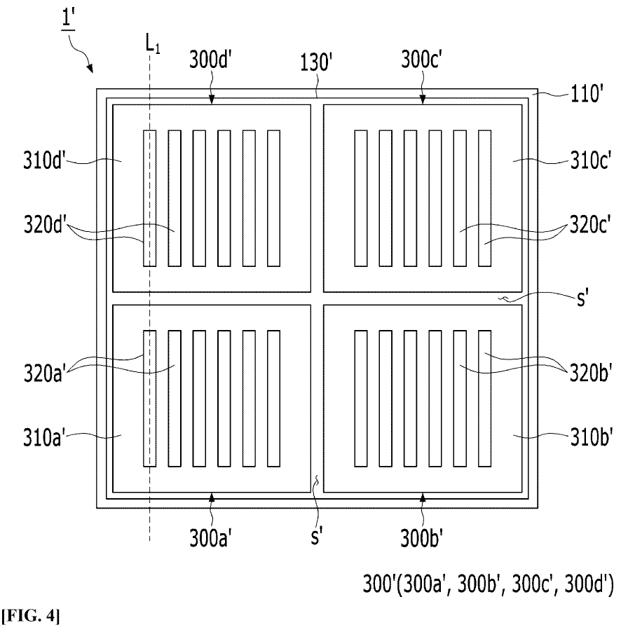

FIG. 4 is a bottom view showing a ceramic substrate unit according to another embodiment of the present disclosure.

As shown in FIG. 4, in a ceramic substrate unit 1′ according to another embodiment of the present disclosure, a heat sink 300′ may be partitioned into four heat sinks 300a′, 300b′, 300c′, and 300d′ whose cross sections are quadrangle and whose areas are the same by a space s'etched in a cross shape. As described above, in the embodiment in which the heat sink 300′ is partitioned into the first heat sink 300a′, the second heat sink 300b′, the third heat sink 300c′, and the fourth heat sink 300d′, when the upper electrode 200 of the ceramic substrate unit 1 is made of an OFC material and has a thickness of 2.0 mm and a thickness of the heat sink 300′ is 3.0 mm, a volume ratio obtained by dividing the total volume of the upper electrode 200 by a total volume of the heat sink 300′ was found to be 0.97. In addition, the average warping value in the case of negative warpage at 200° C. or higher was about 0.035 mm and was found to be very small value.

As a result, the average warping value of another embodiment in which the volume ratio of the upper electrode 200 and the heat sink 300′ was 0.97 was 0.035 mm, which was a relatively much smaller value than the average warping value of one embodiment in which the volume ratio of the upper electrode 200 and the heat sink 300 was 0.9 was 0.150 mm. As described above, the closer the volume ratio of the upper electrode 200 and the heat sink 300′ is to 1.0, the more the warpage can be suppressed.

Meanwhile, in the first to fourth heat sinks 300a′, 300b′, 300c′, and 300d′ shown in FIG. 4, the two heat sinks whose end portions face may each have the protrusion 320a′, 320b′, 320c′, or 320d′ located on the same virtual line when the virtual line is drawn in a direction in which the end portions face. As an example, the first heat sink 300a′ and the fourth heat sink 300d′ whose end portions face may each have the protrusion 320a′ or 320d′ located on a first virtual line L₁ that is the same virtual line when the first virtual line L₁ is drawn in a direction in which the end portions face.

Although FIG. 4 shows an example in which the heat sink is partitioned into four heat sinks having a quadrangular cross section, the present disclosure is not limited thereto, and the heat sink may be partitioned to have various shapes such as a triangle by the space formed by etching the heat sink and designed to be maximally partitioned into 16 heat sinks.

Meanwhile, the heat sink 300 may be used to dissipate heat generated from the semiconductor chip mounted on the upper electrode 200 and made of a material capable of increasing heat dissipation efficiency. As an example, the heat sink 300 may be made of at least one of Cu, Al, AlSiC, CuMo, CuW, Cu/CuMo/Cu, Cu/Mo/Cu, and Cu/W/Cu, or a composite material thereof. Here, the materials of Cu, Al, AlSiC, CuMo, CuW, Cu/CuMo/Cu, Cu/Mo/Cu, and Cu/W/Cu may have excellent thermal conductivity, and the materials of AlSiC, CuMo, CuW, Cu/CuMo/Cu, Cu/Mo/Cu, and Cu/W/Cu may have low thermal expansion coefficients, thereby minimizing the occurrence of warpage when bonded to the ceramic substrate 100.

The heat sink 300 may be formed to have a thickness of 0.6 mm or more and 9.0 mm or less. The heat sink 300 may made of any one of Cu, Al, a CuMo alloy, and a CuW alloy, thereby having excellent thermal conductivity, and may be formed in a relatively large thickness of 0.6 mm or more and 9.0 mm or less corresponding to the upper electrode 200, thereby suppressing warpage and also improving heat dissipation performance due to widely spread heat dissipation. Therefore, even when high-temperature heat is generated from the semiconductor chip, heat can be effectively dissipated by the heat sink 300, and thus the semiconductor chip can operate stably without deterioration.

The heat sink 300 may be bonded to the lower metal layer 130 of the ceramic substrate 100 via the second bonding layer 20. In this case, the second bonding layer 20 may be a brazing bonding layer or an Ag sintering bonding layer made of a material including at least one of Ag, Cu, AgCu, and AgCuTi. When the second bonding layer 20 is a brazing bonding layer, the brazing bonding layer may be disposed between the lower metal layer 130 of the ceramic substrate 100 and the heat sink 300 and may integrally bond the ceramic substrate 100 and the heat sink 300 at a brazing temperature. The brazing temperature may be 450° C. or higher. Ag, AgCu, and AgCuTi may serve to increase bonding strength due to high thermal conductivity and at the same time, facilitate heat transfer between the ceramic substrate 100 and the heat sink 300, thereby increasing heat dissipation efficiency.

When the second bonding layer 20 is an Ag sintered bonding layer, the second bonding layer 20 may be made of a material including an Ag sintered body. For example, when the second bonding layer 20 is an Ag sintered body film, the Ag sintered body film may be disposed between the lower metal layer 130 of the ceramic substrate 100 and the heat sink 300, and in this state, by applying a pressure to the above assembly and hardening the same, the ceramic substrate 100 and the heat sink 300 may be integrally bonded. As described above, a method of hardening the Ag sintered body film enables bonding at a relatively low pressure and low temperature, has high high-temperature stability, and has excellent bonding strength of about 80 MPa. As described above, the ceramic substrate 100 and the heat sink 300 may be airtightly bonded by the bonding method such as the brazing bonding or the Ag sintering bonding, may have a high bonding strength capable of withstanding a water pressure, a hydraulic pressure, etc., and have excellent high-temperature reliability. The ceramic substrate 100 and the heat sink 300 may be temporarily bonded by thermochemical bonding and then brazing-bonded or Ag sintering-bonded. In this case, the thermochemical bonding may be bonding using heat fusion, an adhesive, a gluing agent, etc.

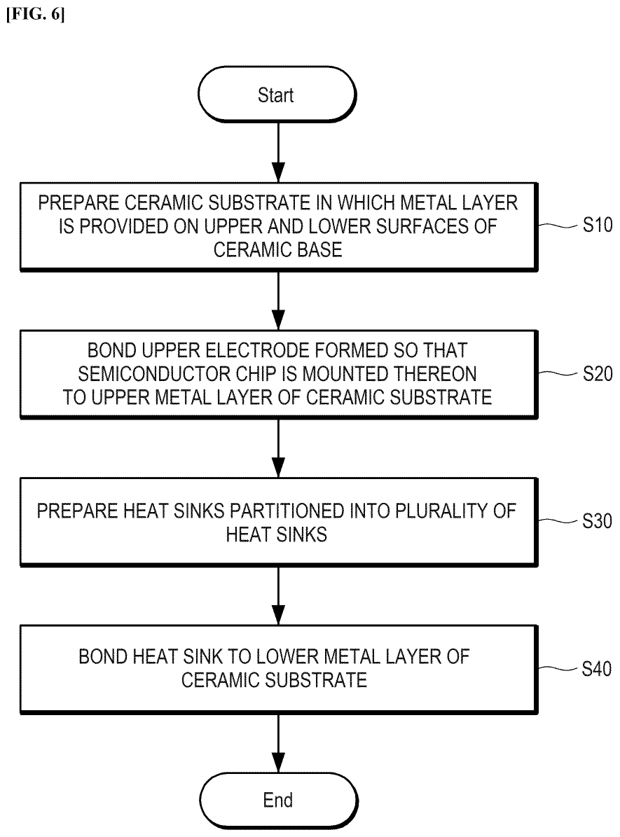

FIG. 6 is a flowchart showing a method of manufacturing the ceramic substrate unit according to one embodiment of the present disclosure.

As shown in FIG. 6, a method of manufacturing the ceramic substrate unit according to one embodiment of the present disclosure may include preparing the ceramic substrate 100 having the metal layers 120 and 130 provided on the upper and lower surfaces of the ceramic base 110 (S10), bonding the upper electrode 200 formed so that the semiconductor chip is mounted thereon to the upper metal layer 120 of the ceramic substrate 100 (S20), preparing the heat sink 300 partitioned into the plurality of heat sinks (S30), and bonding the heat sink 300 to the lower metal layer 130 of the ceramic substrate 100 (S40).

In the preparing of the ceramic substrate 100 (S10), the ceramic substrate 100 may be any one of an AMB substrate, a DBC substrate, and a TPC substrate in which the metal layers 120 and 130 are provided on the upper and lower surfaces of the ceramic base 110.

In the bonding of the upper electrode 200 to the upper metal layer 120 of the ceramic substrate 100 (S20), the upper electrode 200 may be formed in a shape corresponding to the upper metal layer 120 of the ceramic substrate 100 and provided to have a predetermined thickness. Since the upper electrode 200 is made of any one of Cu, Al, a CuMo alloy, and a CuW alloy and formed in a relatively large thickness of 0.6 mm or more to 9.0 mm or less, the upper electrode 200 can be applied to high-output power conversion power modules by having excellent electrical conductivity and thermal conductivity.

The bonding of the upper electrode 200 to the upper metal layer 120 of the ceramic substrate 100 (S20) may include bonding the upper electrode 200 to the upper metal layer 120 via the first bonding layer 10 disposed between the upper metal layer 120 of the ceramic substrate 100 and the upper electrode 200, and the first bonding layer 10 may be made of a material including at least one of Ag, Cu, AgCu, and AgCuTi, or a material including an Ag sintered body. When the first bonding layer 10 is a brazing bonding layer made of the material including at least one of Ag, Cu, AgCu, and AgCuTi, the brazing bonding layer may be disposed between the upper metal layer 120 of the ceramic substrate 100 and the upper electrode 200 and may integrally bond the ceramic substrate 100 and the upper electrode 200 at a brazing temperature. The first bonding layer 10 may be formed by any one method of plating, paste application, and foil attachment and may have a thickness of about 0.3 to 3.0 μm. The brazing bonding may be performed at 450° C. or higher, preferably, in a range of 780 to 900° C., and pressing by a jig may be performed during brazing to increase bonding strength.

When the first bonding layer 10 is an Ag sintered bonding layer, the first bonding layer 10 may be made of a material including an Ag sintered body. For example, when the first bonding layer 10 is an Ag sintered body film, the Ag sintered body film may be disposed between the upper metal layer 120 of the ceramic substrate 100 and the upper electrode 200, and in this state, by applying a pressure to the above assembly and hardening the same, the ceramic substrate 100 and the upper electrode 200 may be integrally bonded. As described above, a method of hardening the Ag sintered body film enables bonding at a relatively low pressure and low temperature, has high high-temperature stability, and has excellent bonding strength of about 80 MPa.

The preparing of the heat sink 300 (S30) may include preparing the heat sinks 300a and 300b partitioned into the plurality of heat sinks to have the predetermined volume corresponding to the volume of the upper electrode 200. Since the upper electrode 200 is formed in a pattern shape so that the semiconductor chip is mounted thereon, the upper electrode 200 is designed to have a fixed shape, thickness, length, etc. in many cases. The heat sink 300 also has a limitation to changing the thickness because the heat sink 300 is designed in consideration of a product, process conditions, heat dissipation, etc. When the volume difference between the upper electrode 200 and the heat sink 300 is large, there occurs a phenomenon that the ceramic substrate unit 1 is warped in a high temperature environment. Therefore, according to the present disclosure, it is possible to suppress the warpage phenomenon caused by the volume difference by controlling the volume ratio of the upper electrode 200 and the heat sink 300 to be within the specific range through the plurality of partitioned heat sinks 300a and 300b.

Specifically, the preparing of the heat sink 300 (S30) may include forming the heat sinks 300a and 300b partitioned into the plurality of heat sinks by the space s formed by etching the portion of the heat sink 300 in the thickness direction. Here, the space s may be formed so that the volume ratio obtained by dividing the total volume of the upper electrode 200 by the total volume of the heat sink 300 is within the range of 0.9 to 1.1.

As described above, since the method of manufacturing the ceramic substrate unit according to one embodiment of the present disclosure forms the heat sinks 300a and 300b partitioned into the plurality of heat sinks by the space formed by etching the portion of the heat sink 300 in the thickness direction, the volume ratio of the upper electrode 200 and the heat sink 300 may be controlled to be within the range of 0.9 to 1.1 by adjusting the total volume of the heat sink 300 without changing the thickness of the heat sink 300. As described above, the volume ratio of the upper electrode 200 and the heat sink 300 may be adjusted to be within the specific range, thereby suppressing the warpage phenomenon at a high temperature.

In the preparing of the heat sink 300 (S30), the heat sink 300 may be formed to have a thickness of 0.6 mm or more to 9.0 mm or less. The heat sink 300 may made of any one of Cu, Al, a CuMo alloy, and a CuW alloy, thereby having excellent thermal conductivity, and may be formed in a relatively large thickness of 0.6 mm or more and 9.0 mm or less corresponding to the upper electrode 200, thereby suppressing warpage and also improving heat dissipation performance due to widely spread heat dissipation.

In the preparing of the heat sink 300 (S30), the heat sinks 300a and 300b may include the flat portions 310a and 310b and the plurality of protrusions 320a and 320b, respectively. The flat portions 310a and 310b are portions whose upper surfaces are in direct contact with the lower metal layer 130 and may be provided in the form of a flat plate to maximally increase the bonding areas. The plurality of protrusions 320a and 320b may be disposed on the lower surfaces of the flat portions 310a and 310b at intervals and may form passages through which the refrigerant flows. Here, the flat portions 310a and 310b may be disposed to be spaced apart from each other with the space s interposed therebetween. Thicknesses of the flat portions 310a and 310b may be formed to be larger than thicknesses of the plurality of protrusions 320a and 320b. As an example, when the thicknesses of the flat portions 310a and 310b are 2.0 mm, the thicknesses of the protrusions 320a and 320b may be 1.0 mm. The shapes of the protrusions 320a and 320b may be implemented by mold processing, etching processing, milling processing, and other processing.

The bonding of the heat sink 300 (S40) may include bonding the heat sink 300 to the lower metal layer 130 via the second bonding layer 20 disposed between the lower metal layer 130 of the ceramic substrate 100 and the heat sink 300, and the second bonding layer 20 may be made of a material including at least one of Ag, Cu, AgCu, and AgCuTi, or a material including an Ag sintered body. When the second bonding layer 20 is a brazing bonding layer made of the material including at least one of Ag, Cu, AgCu, and AgCuTi, the brazing bonding layer may be disposed between the lower metal layer 130 of the ceramic substrate 100 and the heat sink 300 and may integrally bond the ceramic substrate 100 and the heat sink 300. The second bonding layer 20 may be formed by any one method of plating, paste application, and foil attachment and may have a thickness of about 0.3 to 3.0 μm. The brazing bonding may be performed at 450° C. or higher, preferably, in a range of 780 to 900° C., and pressing by a jig may be performed during brazing to increase bonding strength.

When the second bonding layer 20 is an Ag sintered bonding layer, the second bonding layer 20 may be made of a material including an Ag sintered body. For example, when the second bonding layer 20 is an Ag sintered body film, the Ag sintered body film may be disposed between the lower metal layer 130 of the ceramic substrate 100 and the heat sink 300, and in this state, by applying a pressure to the above assembly and hardening the same, the ceramic substrate and the heat sink 300 may be integrally bonded. As described above, a method of hardening the Ag sintered body film enables bonding at a relatively low pressure and low temperature, has high high-temperature stability, and has excellent bonding strength of about 80 MPa.

Since the above-described ceramic substrate unit according to the present disclosure has a structure in which the upper electrode 200 and the heat sink 300, which have a thickness of 0.6 mm or more to 9.0 mm or less, are bonded to the upper and lower metal layers 120 and 130 of the ceramic substrate 100, respectively, the ceramic substrate unit can be used for high-output power conversion or applied to a device requiring the guarantee of the thermal characteristics, etc.

In addition, since the ceramic substrate unit according to the present disclosure has the upper electrode 200 and the heat sink 300 brazing-bonded or Ag sintering-bonded to the upper and lower metal layers 120 and 130 of the ceramic substrate 100, respectively, the ceramic substrate unit may have solid bonding strength and excellent thermal conductivity, thereby satisfying high heat dissipation conditions required for power modules.

The above-described ceramic substrate unit according to the present disclosure can secure both multiple and large amount of connections of the semiconductor chip and the heat dissipation effect and further improve the performance of the power modules. The ceramic substrate unit according to the present disclosure can be applied to various devices requiring high power and high heat dissipation characteristics in addition to single-sided or double-sided cooling power modules.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the equivalent scope should be construed as being included in the scope of the present disclosure.

1. A ceramic substrate unit comprising:
a ceramic substrate having a metal layer provided on upper and lower surfaces of a ceramic base; and
an upper electrode bonded to an upper metal layer of the ceramic substrate and formed so that a semiconductor chip is mounted thereon; and
a heat sink bonded to a lower metal layer of the ceramic substrate, wherein the heat sink is partitioned into a plurality of heat sinks.

2. The ceramic substrate unit of claim 1, wherein the upper electrode and the heat sink are each formed in a thickness of 0.6 mm or more to 9.0 mm or less.

3. The ceramic substrate unit of claim 1, wherein the heat sink is partitioned into a plurality of heat sinks by a space formed by etching a portion of the heat sink in a thickness direction.

4. The ceramic substrate unit of claim 1, wherein the heat sink is partitioned into a plurality of heat sinks to have a predetermined volume corresponding to a volume of the upper electrode.

5. The ceramic substrate unit of claim 4, wherein a volume ratio obtained by dividing a total volume of the upper electrode by a total volume of the heat sink ranges from 0.9 to 1.1.

6. The ceramic substrate unit of claim 3, wherein a bottom surface of the lower metal layer is exposed through the space.

7. The ceramic substrate unit of claim 3, wherein the plurality of heat sinks each include:
a flat portion having an upper surface bonded to the lower metal layer; and
a plurality of protrusions disposed on a lower surface of the flat portion and forming a passage through which refrigerant flows, and
the flat portions are disposed to be spaced apart from each other with the space interposed therebetween.

8. The ceramic substrate unit of claim 7, wherein a thickness of the flat portion is larger than a thickness of the protrusion.

9. The ceramic substrate unit of claim 7, wherein the plurality of heat sinks each have the same area of the flat portion.

10. The ceramic substrate unit of claim 7, wherein the plurality of heat sinks each have the same number of protrusions.

11. The ceramic substrate unit of claim 7, wherein two heat sinks whose end portions face among the plurality of heat sinks each have the protrusion located on the same virtual line when the virtual line is drawn in a direction in which the end portions face.

12. The ceramic substrate unit of claim 7, wherein the plurality of protrusions are provided in a bar shape and disposed horizontally at an interval.

13. The ceramic substrate unit of claim 1, further comprising a first bonding layer disposed between the upper metal layer of the ceramic substrate and the upper electrode and bonding the ceramic substrate and the upper electrode,
wherein the first bonding layer is made of a material including at least one of Ag, Cu, AgCu, and AgCuTi or a material including an Ag sintered body.

14. The ceramic substrate unit of claim 1, further comprising a second bonding layer disposed between the lower metal layer of the ceramic substrate and the heat sink and bonding the ceramic substrate and the heat sink,
wherein the second bonding layer is made of a material including at least one of Ag, Cu, AgCu, and AgCuTi or a material including an Ag sintered body.

15. The ceramic substrate unit of claim 1, wherein the upper electrode and the heat sink are made of any one of Cu, Al, and a Cu alloy.

16. A method manufacturing a ceramic substrate unit, comprising:
preparing a ceramic substrate including a metal layer provided on upper and lower surfaces of a ceramic base;
bonding an upper electrode formed so that a semiconductor chip is mounted thereon to an upper metal layer of the ceramic substrate;
preparing heat sinks partitioned into a plurality of heat sinks; and
bonding the heat sink to a lower metal layer of the ceramic substrate.

17. The method of claim 16, wherein the preparing of the heat sink includes forming heat sinks partitioned into the plurality of heat sinks by a space formed by etching a portion of the heat sink in a thickness direction.

18. The method of claim 17, wherein the preparing of the heat sink includes forming the space so that a volume ratio obtained by dividing a total volume of the upper electrode by a total volume of the heat sink ranges from 0.9 to 1.1.

19. The method of claim 16,
wherein the bonding of the upper electrode to the upper metal layer of the ceramic substrate includes bonding the upper electrode to the upper metal layer via a first bonding layer disposed between the upper metal layer and the upper electrode, and
the first bonding layer is made of a material including at least one of Ag, Cu, AgCu, and AgCuTi or a material including an Ag sintered body.

20. The method of claim 16, wherein the bonding of the heat sink includes bonding the heat sink to the lower metal layer via a second bonding layer disposed between the lower metal layer and the heat sink, and
the second bonding layer is made of a material including at least one of Ag, Cu, AgCu, and AgCuTi or a material including an Ag sintered body.
